(19) United States
(12) Patent Application Publication
(10) Pub. No.: US 2020/0167626 A1
(43) Pub. Date: May 28, 2020

(54) SMART CARD AND MANUFACTURING METHOD THEREFOR

(71) Applicant: EXCELSECU DATA TECHNOLOGY CO., LTD., District, Shenzhen, Guangdong (CN)

(72) Inventor: Liuzhang Chen, Guangdong (CN)

(73) Assignee: EXCELSECU DATA TECHNOLOGY CO., LTD., District, Shenzhen, Guangdong (CN)

(21) Appl. No.: 16/610,571

(22) PCT Filed: Aug. 18, 2017
(86) PCT No.: PCT/CN2018/097012

§ 371 Date: Nov. 4, 2019

(30) Foreign Application Priority Data
Aug. 18, 2017 (CN) 201710711738.2

(51) Int. Cl. G06K 19/077; H01L 23/498; H01L 21/48

(52) U.S. Cl. CPC G06K 19/07722; H01L 21/4853; H01L 23/49855

(57) ABSTRACT

Disclosed are a smart card and a manufacturing method therefor, the method includes: sequentially placing a first substrate, a middle frame and a circuit board, attaching a spacer to a periphery of the circuit board, pouring glue into the middle frame and laminating the middle frame, machining a through hole in the first substrate and an extension plate to expose a contact area; and fixing a contact module on the contact area, and punching for forming.

### FIELD

The disclosure belongs to the field of smart card technologies, and more particularly, to a smart card and a manufacturing method therefor.

### BACKGROUND

In the existing IC (Integrated Circuit) card manufacturing process, a substrate of an IC card is firstly manufactured by glue pouring and laminating, then a through hole for placing a chip is machined in the substrate of the IC card, a 7816 chip is welded with a bonding pad (or an antenna) on a FPC board at high temperature, or the antenna in the card is picked out firstly and then welded with the 7816 chip. However, for the IC card manufacturing process in the prior art, distance between the FPC board and an outer surface of the substrate of the IC card cannot be precisely positioned due to the fact that the FPC (Flexible Printed Circuit) board may be squeezed by glue when the substrate of the IC card is manufactured by glue pouring and laminating, so that glue may be poured between a bottom of the through hole and the FPC board, that is, the glue may be poured at a joint between the 7816 chip and the FPC board, resulting in poor contact. Alternatively, a surface of the FPC board may be damaged during machining, resulting in damages to the FPC board. High temperature may damage a surface of the card, it is more troublesome to pick out the antenna from the card before welding, and the fraction defective is relatively high.

### SUMMARY

The disclosure is intended to provide a smart card and a manufacturing method therefor to solve the technical problem in the prior art that distance between a FPC board and an outer surface of a substrate of an IC card cannot be precisely positioned due to the fact that the FPC board may be squeezed by glue when the substrate of the IC card is manufactured by glue pouring and laminating.

In order to achieve the objective above, the technical solution adopted in the disclosure is to provide a method for manufacturing a smart card, which includes the following steps of:

S1) stacking and fixing a middle frame at a bottom side of a first substrate;

S2) disposing a circuit board at a bottom side of the middle frame, wherein the circuit board is provided with a contact area facing directly the extension plate;

S3) pouring glue into the middle frame;

S4) machining a through hole in the first substrate and the middle frame, and exposing the contact area at a bottom of the through hole; and

S5) placing a contact module in the through hole, connecting the contact module with the contact area, and punching for forming.

Further, the method includes, after step S2), attaching a spacer to a periphery of the circuit board.

Further, the method includes, after step S3), stacking a second substrate at bottom sides of the circuit board and the spacer, and fixedly connecting the first substrate, the middle frame, the circuit board, the spacer and the second substrate by laminating.

Further, step S3) includes pouring glue into the middle frame through a gap formed between the spacer and the circuit board.

Further, in step S4), the through hole has a depth equal to a sum of thicknesses of the first substrate and the middle frame.

Further, step S5) includes disposing the contact module in the through hole and fixedly connecting the contact module with the contact area through a conductive adhesive.

Further, the middle frame is integrally formed with the extension plate, the extension plate has a length and a width both smaller than those of the middle frame.

Another objective of the disclosure is intended to provide a smart card, which includes: a first substrate; a contact module; a middle frame stacked at one side of the first substrate, wherein the middle frame is extended, at an inner side of the middle frame, with an extension plate, and a through hole, in which the contact module is accommodated, is opened through both the first substrate and the extension plate; and a circuit board disposed at one side of the middle frame away from the first substrate, wherein the circuit board has a contact area facing towards the through hole and electrically connected with the contact module.

Further, the smart card further includes: a spacer disposed outside the circuit board and fixedly connected with the middle frame; and a second substrate disposed at one side of the spacer away from the first substrate.

Further, a gap is formed between the spacer and the circuit board, and the first substrate, the middle frame, the circuit board, the spacer and the second substrate are bonded by pouring glue.

Further, the through hole has a depth equal to a sum of thicknesses of the first substrate and the middle frame.

Further, the contact module and the contact area are fixedly connected through a conductive adhesive.

Further, the middle frame has an outer shape matched with that of the first substrate, and the spacer has an outer shape matched with that of the middle frame.

Further, the circuit board is bonded with the first substrate, and the middle frame is bonded with the first substrate.

The smart card and the manufacturing method therefor according to the disclosure have the beneficial effects as follows: compared with the prior art, by providing a middle frame between the first substrate and the circuit board, because thicknesses of the first substrate and the middle frame are constant, and the contact area is disposed inside the extension plate of the middle frame, depth of the machined through hole may be set according to a sum of the thicknesses of the first substrate and the middle frame when the through hole is machined, so that the through hole can be precisely machined to expose the contact area without damages to the circuit board caused by machining.

### BRIEF DESCRIPTION OF THE DRAWINGS

In order to illustrate the technical solutions in the embodiments of the disclosure more clearly, the drawings used in the description of the embodiments and the prior art will be briefly described below. Obviously, the drawings in the following description are merely some embodiments of the disclosure. Those of ordinary skilled in the art can also obtain other drawings according to these drawings without any creative work.

FIG. 1 is a front view of a smart card according to an embodiment of the disclosure;

FIG. 2 is a cross-sectional view of the smart card taken along line A-A in FIG. 1; and

FIG. 3 is a front view of the smart card according to an embodiment of the disclosure.

The reference numerals in the drawings are as follows:

1 refers to first substrate; 2 refers to middle frame; 3 refers to second substrate; 4 refers to circuit board; 5 refers to spacer; 6 refers to through hole; 7 refers to contact module; 8 refers to conductive adhesive; 9 refers to glue; 21 refers to extension plate; and 41 refers to contact area.

### DETAILED DESCRIPTION OF THE EMBODIMENTS

To make the technical problems to be solved by the disclosure, the technical solutions and the beneficial effects clearer, the disclosure is further described in detail hereinafter with reference to the accompanying drawings and the embodiments. It should be understood that the specific embodiments described herein are merely for explaining the disclosure, and are not used for limiting the disclosure.

It should be noted that when an element is referred to as being “fixed” or “disposed” to the other element, the element can be directly or indirectly fixed or disposed to the other element. When an element is referred to as being “connected” with the other element, the element can be directly or indirectly connected with the other element.

It should be understood that, the orientation or position relationship indicated by the terms “length”, “width”, “upper”, “lower”, “front”, “rear”, “left”, “right”, “vertical”, “horizontal”, “top”, “bottom”, “inner”, “outer” and the like is the orientation or position relationship based on the drawings, which is merely used for facilitating the description of the disclosure and the simplification of description instead of indicating or implying that the indicated device or element must have a specific orientation and be constructed and operated in a specific orientation. Therefore, it cannot be understood as limiting the disclosure.

Moreover, the terms “first” and “second” are merely used for facilitating description, and cannot be construed as indicating or implying the relative importance or implicitly indicating the number of technical features referred. Therefore, the feature defined by “first” or “second” can explicitly or implicitly include one or more features described. In the description of the disclosure, the meaning of “a plurality of” refers to two or more, unless otherwise defined specifically.

A method for manufacturing a smart card according to the disclosure is now described with reference to FIG. 1 to FIG. 3. The method for manufacturing a smart card comprises the following steps of:

S1) stacking and fixing a middle frame 2 at a bottom side of a first substrate 1, wherein the middle frame 2 is extended, at an inner side of the middle frame, with an extension plate 21;

S2) disposing a circuit board 4 at a bottom side of the middle frame 2, wherein the circuit board 4 is provided with a contact area 41 facing directly the extension plate, and a spacer 5 is attached to a periphery of the circuit board 4;

S3) pouring glue into the middle frame 2 through a gap between the spacer 5 and the circuit board 4, stacking a second substrate 3 on bottom sides of the circuit board 4 and the spacer 5 after pouring the glue into the middle frame 2, and fixedly connecting the first substrate 1, the middle frame 2, the circuit board 4, the spacer 5 and the second substrate 3 by laminating;

S4) machining a through hole 6 in the first substrate 1 and the extension plate 21, wherein the through hole 6 has a depth equal to a sum of thicknesses of the first substrate 1 and the middle frame 2, and exposing the contact area 41 at a bottom of the through hole 6; and

S5) placing a contact module 7 in the through hole 6, fixedly connecting the contact module 7 with the contact area 41 through a conductive adhesive 8 so that the contact module 7 is bonded to the contact area 41, and punching for forming.

For the method for manufacturing a smart card according to the disclosure, compared with the prior art, by providing the middle frame 2 between the first substrate 1 and the circuit board 4, because thicknesses of the first substrate 1 and the middle frame 2 are constant and the contact area 41 is disposed inside the extension plate 21 of the middle frame 2, depth of the machined through hole 6 may be set according to a sum of the thicknesses of the first substrate 1 and the middle frame 2 when the through hole 6 is machined, so that the through hole 6 can be precisely machined to expose the contact area 41 without damages to the circuit board 4 caused by machining.

Specifically, the through hole 6 may be machined, from an upper surface of the first substrate 1, by a depth which is a sum of thicknesses of the first substrate 1 and the middle frame 2. Since the thicknesses of the first substrate 1 and the middle frame 2 are both determined, the depth of the through hole 6 can be determined from the determined thicknesses, so that the through hole 6 can be precisely machined to expose the contact area 41 without damages to the circuit board 4 caused by machining.

By using the conductive adhesive 8, the contact module 7 may be fixedly bonded to and electrically connected with the contact area 41, without any relative displacement therebetween. The conductive adhesive 8 is a conductive colloid, and generally has main components of matrix resin and conductive filler, i.e. conductive particles, which is not exclusively limited herein.

The contact module 7 may be a 7816 chip module including a carrier tape unit and a 7816 chip, or may be a separate carrier tape unit, and the 7816 chip may fixed on the circuit board. The contact module 7 is placed in the through hole 6 and is directly welded onto a conductive medium of the contact area 41 of the circuit board 4. An antenna coil may also be disposed around the circuit board 4, and the contact module 7 is connected with the antenna coil to manufacture a smart card. The smart card has high production efficiency, low production cost, high safety and high customer recognition. The contact module 7 is a contact module with the 7816 chip or other chips, the contact module 7 is welded with conductive mediums at tail ends of lead wires at two ends of the antenna coil. The contact module 7 may be connected with the antenna coil on the circuit board 4 to manufacture a double-interface smart card. The contact area 41 is a bare copper area located at one side of the circuit board 4 close to the first substrate 1 and positioned corresponding to the through hole 6. The extension plate 21 is disposed at an upper side of the contact area 41, so that the contact area 41 may be exposed after machining the extension plate 21. The contact module 7 is bonded to the contact area 41, and a pin of the contact module 7 is electrically connected with the bare copper area.

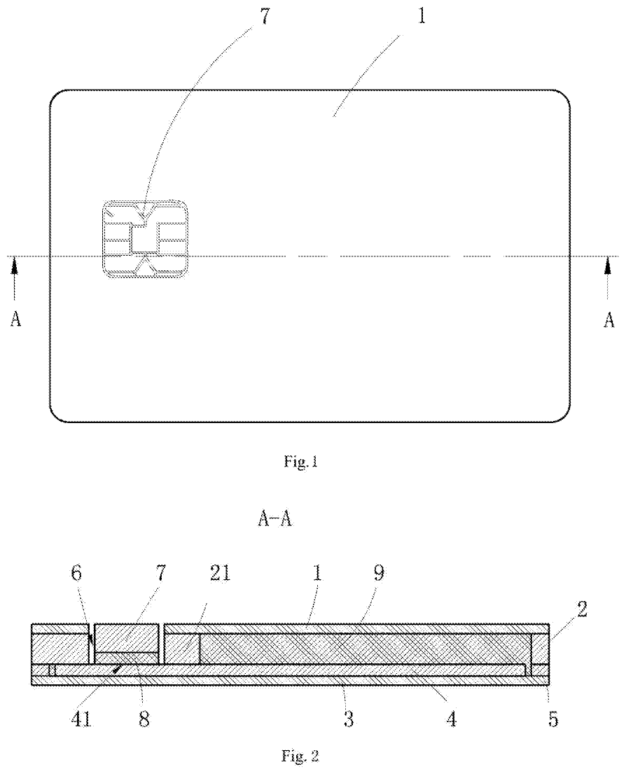

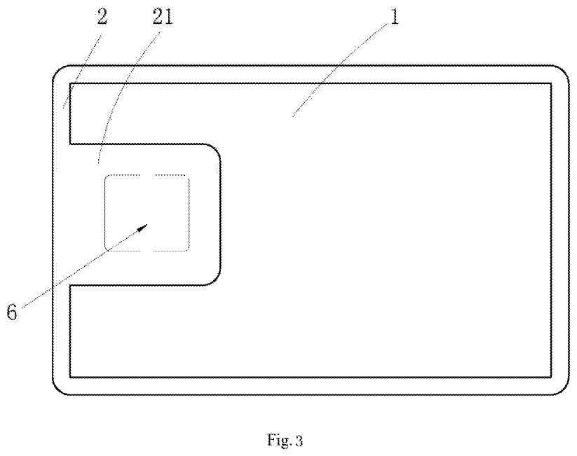

Further, with reference to FIG. 2, as a specific embodiment of the method for manufacturing a smart card according to the disclosure, the through hole 6 has a size greater than or equal to that of the contact module 7. Specifically, the through hole 6 has a length and a width respectively greater than or equal to those of the contact module 7 so that the contact module 7 can be simply placed and fixed inside the through hole 6, and a height greater than or equal to that of the contact module 7 so that wear on an upper surface of the contact module 7 can be avoided. Certainly, according to actual conditions and specific requirements, in other embodiments of the disclosure, the height of the through hole 6 may also be smaller than that of the contact module 7, which is not exclusively limited herein.

Further, with reference to FIG. 1 to FIG. 3, as a specific embodiment of the method for manufacturing a smart card according to the disclosure, an outer shape of the middle frame 2 is matched with that of the first substrate 1. Specifically, shapes of the first substrate 1 and the second substrate 3 are a shape of a standard card, which are rectangular. The circuit board 4 is of a rectangular shape, the outer shape of the middle frame 2 is rectangular, and a cross section of an accommodating groove of the middle frame 2 is of a rectangular shape. An outer shape of the circuit board 4 is matched with the cross section of the accommodating groove of the middle frame 2, thus having a compact structure. Certainly, according to actual conditions and specific requirements, the smart card in other embodiments of the disclosure may also be a non-standard card, the first substrate 1, the middle frame 2, the circuit board 4, and the second substrate 3 are not limited to be of a rectangular shape, but can be freely customized, which are not exclusively limited herein.

Further, with reference to FIG. 1 to FIG. 3, as a specific embodiment of the method for manufacturing a smart card according to the disclosure, an outer shape of the spacer 5 is matched with that of the middle frame 2. Specifically, the spacer 5 is disposed at one side of the middle frame 2 away from the first substrate 1, the spacer 5 is disposed around the circuit board 4 and has a thickness equal to that of the circuit board 4. The spacer 5 is simple in assembly, and can effectively position and protect the circuit board 4. Meanwhile, the first substrate 1, the middle frame 2, the circuit board 4, the spacer 5 and the second substrate 3 can be fixedly connected by glue pouring and laminating conveniently.

Further, with reference to FIG. 1 to FIG. 3, as a specific embodiment of the method for manufacturing a smart card according to the disclosure, the circuit board 4 is bonded to the first substrate 1, and the middle frame 2 is bonded to the first substrate 1. Specifically, the machining is simple by means of bonding which has a reliable connection. In an actual solution, the circuit board 4 and the middle frame 2 are bonded to the first substrate 1 by brushing glue before pouring glue. Connection between the circuit board 4 and the second substrate 3, and connection between the middle frame 2 and the second substrate 3 are realized by pouring glue. Certainly, according to actual conditions and specific requirements, in other embodiments of the disclosure, welding or other existing connection methods can also be used between the circuit board 4 and the first substrate 1, between the middle frame 2 and the first substrate 1, between the circuit board 4 and the second substrate 3, and between the middle frame 2 and the second substrate 3, which are not exclusively limited herein.

With reference to FIG. 1 to FIG. 3, a smart card according to the first embodiment of the disclosure includes: a first substrate 1; a contact module 7 with a 7816 chip; a middle frame 2 stacked at one side of the first substrate 1, wherein the middle frame 2 is extended at an inner side with an extension plate 21, and a through hole 6, in which the contact module 7 is accommodated, is opened through both the first substrate 1 and the extension plate 21; and a circuit board 4 disposed at one side of the middle frame 2 away from the first substrate 1, wherein the circuit board 4 has a contact area 41 connected with the contact module 7 at a position corresponding to the through hole 6.

With reference to FIG. 1 to FIG. 3, for the smart card according to the first embodiment of the disclosure, the middle frame 2 is integrally formed with the extension plate 21, the extension plate 21 has a length smaller than that of the middle frame 2 and a width smaller than that of the middle frame 2. Specifically, the extension plate 21 is disposed inside the middle frame 2 at one side of the middle frame 2 and integrally formed with the middle frame 2. The length and width of the extension plate 21 are both smaller than those of the middle frame 2, an upper surface of the extension plate 21 is abutted against a lower surface of the first substrate 1, and positioning can be realized through an opening in the extension plate 21, thus ensuring a positioning precision.

For the smart card according to the disclosure, compared with the prior art, by providing the middle frame 2 between the first substrate 1 and the circuit board 4, because thicknesses of the first substrate 1 and the middle frame 2 are constant and the contact area 41 is disposed inside the extension plate 21 of the middle frame 2, depth of the machined through hole 6 may be set according to a sum of the thicknesses of the first substrate 1 and the middle frame 2 when the through hole 6 is machined, so that the through hole 6 can be precisely machined to expose the contact area 41 without damages to the circuit board 4 caused by machining.

Specifically, the extension plate 21 is disposed inside the middle frame 2 at one side of the middle frame 2 and integrally formed with the middle frame 2, the length and the width of the extension plate 21 are both smaller than those of the middle frame 2, and the upper surface of the extension plate 21 is abutted against the lower surface of the first substrate 1. Therefore, the through hole 6 may be machined, from the upper surface of the first substrate 1, by a depth which is a sum of thicknesses of the first substrate 1 and the middle frame 2. Moreover, since the thicknesses of the first substrate 1 and the middle frame 2 are both determined, the depth of the through hole 6 can be determined from the determined thicknesses, so that the through hole 6 can be precisely machined to expose the contact area 41 without damages to the circuit board 4 caused by machining.

Preferably, the circuit board 4 is a flexible printed circuit board 4, with high reliability, excellent flexibility, high wiring density, light weight, thin thickness and good bending property, thus being suitable for use in the smart card.

Further, with reference to FIG. 2, as a specific embodiment of the smart card according to the disclosure, the smart card further includes: a spacer 5 disposed outside the circuit board 4 and fixedly connected with the middle frame 2; and a second substrate 3 disposed at one side of the spacer 5 opposite to the first substrate 1. Specifically, the spacer 5 is enclosed outside the circuit board 4 for protecting the circuit board 4. The second substrate 3 and the first substrate 1 are oppositely disposed, the circuit board 4 is fixed between the first substrate 1 and the second substrate 3, and a space is formed between the first substrate 1 and the second substrate 3. The first substrate 1 and the second substrate 3 are respectively arranged at both sides of the circuit board 4 to protect the circuit board 4. Certainly, according to actual conditions and specific requirements, in other embodiments of the disclosure, only one of the first substrate 1 and the second substrate 3 may be provided, which is not exclusively limited herein.

Further, with reference to FIG. 2, as a specific embodiment of the smart card according to the disclosure, a gap may be formed between the spacer 5 and the circuit board 4. Moreover, the first substrate 1, the middle frame 2, the circuit board 4, the spacer 5 and the second substrate 3 are bonded by pouring glue. Specifically, the gap between the spacer 5 and the circuit board 4 may be used for glue pouring, glue 9 may be poured between the first substrate 1 and the second substrate 3 to define positions of the first substrate 1, the middle frame 2, the circuit board 4, the spacer 5 and the second substrate 3, and glue pouring between the spacer 5 and the circuit board 4 can also enable bonding of the spacer 5 to the circuit board 4. Certainly, according to actual conditions and specific requirements, in other embodiments of the disclosure, the gap may also be formed at one side, two sides or three sides between the spacer 5 and the circuit board 4, and the spacer 5 may abutted against the circuit board 4 at the remaining side(s), which is not exclusively limited herein.

Further, with reference to FIG. 1 to FIG. 3, as a specific embodiment of the smart card according to the disclosure, the depth of the through hole 6 is equal to the sum of thicknesses of the first substrate 1 and the middle frame 2. Specifically, the through-hole 6 may be machined, from an upper surface of the first substrate 1, by a depth which is the sum of the thicknesses of the first substrate 1 and the middle frame 2. Since the thicknesses of the first substrate 1 and the middle frame 2 are both determined, the depth of the through-hole 6 can be determined from the determined thicknesses, so that the through hole 6 can be precisely machined to expose the contact area 41 without damages to the circuit board 4 caused by machining.

Further, with reference to FIG. 1 to FIG. 3, as a specific embodiment of the smart card according to the disclosure, the contact module 7 and the contact area 41 are fixedly connected through a conductive adhesive 8. Specifically, by using the conductive adhesive 8, the contact module 7 may be fixedly bonded to and electrically connected with the contact area 41, without any relative displacement therebetween. The conductive adhesive 8 is a conductive colloid, and generally has main components of matrix resin and conductive filler, i.e. conductive particles, which are not exclusively limited herein.

Further, with reference to FIG. 1 to FIG. 3, as a specific embodiment of the smart card according to the disclosure, the through hole 6 has a size greater than or equal to that of the contact module 7. Specifically, the through hole 6 has a length and a width respectively greater than or equal to those of the contact module 7 so that the contact module 7 can be simply placed and fixed inside the through hole 6, and a height greater than or equal to that of the contact module 7 so that wear on an upper surface of the contact module 7 can be avoided. Certainly, according to actual conditions and specific requirements, in other embodiments of the disclosure, the height of the through hole 6 may also be smaller than that of the contact module 7, which is not exclusively limited herein.

Further, with reference to FIG. 1 to FIG. 3, as a specific embodiment of the smart card according to the disclosure, an outer shape of the middle frame 2 is matched with that of the first substrate 1. Specifically, shapes of the first substrate 1 and the second substrate 3 are a shape of a standard card, which are rectangular. The circuit board 4 is of a rectangular shape, the outer shape of the middle frame 2 is rectangular, and a cross section of an accommodating groove of the middle frame 2 is rectangular. An outer shape of the circuit board 4 is matched with the cross section of the accommodating groove of the middle frame 2, thus having a compact structure. Certainly, according to actual conditions and specific requirements, the smart card in other embodiments of the disclosure may also be a non-standard card, the first substrate 1, the middle frame 2, the circuit board 4, and the second substrate 3 are not limited to be of a rectangular shape but can be freely customized, which are not exclusively limited herein.

Further, with reference to FIG. 1 to FIG. 3, as a specific embodiment of the smart card according to the disclosure, an outer shape of the spacer 5 is matched with that of the middle frame 2. Specifically, the spacer 5 is disposed at one side of the middle frame 2 away from the first substrate 1, the spacer 5 is disposed around the circuit board 4 and has a thickness equal to that of the circuit board 4. The spacer 5 is simple in assembly, and can effectively position and protect the circuit board 4. Meanwhile, the first substrate 1, the middle frame 2, the circuit board 4, the spacer 5 and the second substrate 3 can be fixedly connected by glue pouring and laminating conveniently.

Further, with reference to FIG. 1 to FIG. 3, as a specific embodiment of the smart card according to the disclosure, the circuit board 4 is bonded to the first substrate 1, and the middle frame 2 is bonded to the first substrate 1. Specifically, the machining is simple by means of bonding which has a reliable connection. In an actual solution, the circuit board 4 and the middle frame 2 are bonded to the first substrate 1 by brushing glue before pouring glue. Connection between the circuit board 4 and the second substrate 3, and connection between the middle frame 2 and the second substrate 3 are realized by pouring glue. Certainly, according to actual conditions and specific requirements, in other embodiments of the disclosure, welding or other existing connection methods can also be used between the circuit board 4 and the first substrate 1, between the middle frame 2 and the first substrate 1, between the circuit board 4 and the second substrate 3, and between the middle frame 2 and the second substrate 3, which are not exclusively limited herein.

Further, with reference to FIG. 1 to FIG. 3, as a specific embodiment of the smart card according to the disclosure, an outer shape of the middle frame 2 is matched with that of the first substrate 1, and an outer shape of the spacer 5 is matched with that of the middle frame 2. Specifically, shapes of the first substrate 1 and the second substrate 3 are a shape of a standard card, which are rectangular. The circuit board 4 is of a rectangular shape, the outer shape of the middle frame 2 is rectangular, and a cross section of an accommodating groove of the middle frame 2 is rectangular. An outer shape of the circuit board 4 is matched with the cross section of the accommodating groove of the middle frame 2, thus having a compact structure. The spacer 5 is disposed at one side of the middle frame 2 away from the first substrate 1, the spacer 5 is disposed around the circuit board 4 and has a thickness equal to that of the circuit board 4, the spacer 5 is simple in assembly, and can effectively position and protect the circuit board 4. Meanwhile, the first substrate 1, the middle frame 2, the circuit board 4, the spacer 5 and the second substrate 3 may be fixedly connected by glue pouring and laminating conveniently. Certainly, according to actual conditions and specific requirements, the smart card in other embodiments of the disclosure may also be a non-standard card, the first substrate 1, the middle frame 2, the circuit board 4, and the second substrate 3 are not limited to be of a rectangular shape but can be freely customized, which are not exclusively limited herein.

Further, with reference to FIG. 1 to FIG. 3, as a specific embodiment of the smart card according to the disclosure, the circuit board 4 is bonded to the first substrate 1, and the middle frame 2 is bonded to the first substrate 1. Specifically, the machining is simple by means of bonding which has a reliable connection. In an actual solution, the circuit board 4 and the middle frame 2 are bonded to the first substrate 1 by brushing glue before pouring glue. Connection between the circuit board 4 and the second substrate 3, and connection between the middle frame 2 and the second substrate 3 are realized by pouring glue. Certainly, according to actual conditions and specific requirements, in other embodiments of the disclosure, welding or other existing connection methods can also be used between the circuit board 4 and the first substrate 1, between the middle frame 2 and the first substrate 1, between the circuit board 4 and the second substrate 3, and between the middle frame 2 and the second substrate 3, which are not exclusively limited herein.

Above are merely preferred embodiments of the disclosure, but are not intended to limit the disclosure. Any modifications, equivalent substitutions and improvements without departing from the concept and principle of the disclosure shall all fall within the protection scope of the disclosure.

1. A method for manufacturing a smart card, comprising the following steps of:
S1) stacking and fixing a middle frame at a bottom side of a first substrate, wherein the middle frame is extended, at an inner side of the middle frame, with an extension plate;
S2) disposing a circuit board at a bottom side of the middle frame, wherein the circuit board is provided with a contact area facing directly the extension plate;
S3) pouring glue into the middle frame;
S4) machining a through hole in the first substrate and the extension plate, and exposing the contact area at a bottom of the through hole; and
S5) placing a contact module in the through hole, connecting the contact module with the contact area, and punching for forming.

2. The method for manufacturing a smart card of claim 1, further comprising, after step S2), attaching a spacer to a periphery of the circuit board.

3. The method for manufacturing a smart card of claim 2, further comprising, after step S3), stacking a second substrate at bottom sides of the circuit board and the spacer, and fixedly connecting the first substrate, the middle frame, the circuit board, the spacer and the second substrate by laminating.

4. The method for manufacturing a smart card of claim 2, wherein step S3) comprises pouring glue into the middle frame through a gap formed between the spacer and the circuit board.

5. The method for manufacturing a smart card of claim 1, wherein in step S4), the through hole has a depth equal to a sum of thicknesses of the first substrate and the middle frame.

6. The method for manufacturing a smart card of claim 1, wherein step S5) comprises, disposing the contact module in the through hole and fixedly connecting the contact module with the contact area through a conductive adhesive.

7. The method for manufacturing a smart card of claim 1, wherein the middle frame is integrally formed with the extension plate, and the extension plate has a length smaller than a length of the middle frame, and a width smaller than a width of the middle frame.

8. A smart card, comprising:
a first substrate;
a contact module;
a middle frame stacked at one side of the first substrate, wherein the middle frame is extended, at an inner side of the middle frame, with an extension plate, and a through hole, in which the contact module is accommodated, is opened through both the first substrate and the extension plate; and
a circuit board disposed at one side of the middle frame away from the first substrate, wherein the circuit board has a contact area facing towards the through hole and electrically connected with the contact module.

9. The smart card of claim 8, further comprising: a spacer disposed outside the circuit board and fixedly connected with the middle frame; and a second substrate disposed at one side of the spacer away from the first substrate.

10. The smart card of claim 9, wherein a gap is formed between the spacer and the circuit board, and the first substrate, the middle frame, the circuit board, the spacer and the second substrate are bonded by pouring glue.

11. The smart card of claim 8, wherein the through hole has a depth equal to a sum of thicknesses of the first substrate and the middle frame.

12. The smart card of claim 9, wherein the contact module and the contact area are fixedly connected through a conductive adhesive.

13. The smart card of claim 8, wherein the middle frame has an outer shape matched with an outer shape of the first substrate, and the spacer has an outer shape matched with the outer shape of the middle frame.

14. The smart card of claim 8, wherein the circuit board is bonded with the first substrate, and the middle frame is bonded with the first substrate.
